(19) United States
(12) Patent Application Publication
(10) Pub. No.: US 2012/0267491 A1
(43) Pub. Date: Oct. 25, 2012

(54) LOCKING DEVICE

(76) Inventor: Ronald On Ho CHIU, Hong Kong (HK)

(21) Appl. No.: 13/449,920

(22) Filed: Apr. 18, 2012

(30) Foreign Application Priority Data
Apr. 19, 2011 (HK) 11103974.1

(51) Int. Cl. H05K 7/14

(52) U.S. Cl. 248/221.11

(57) ABSTRACT

A locking device (10) comprising: locking members (20) to releasably engage with a locking surface (31); an actuating member (11) operatively connected to the locking members (20); hinges (201) to pivotally connect the locking device (10) to the stand (200); and a raised lip portion (23) defined on at peripheral edge of each locking member (20) to engage with the locking surface (31); wherein the actuating member (11) is pushed in an inwardly direction by a single finger movement that is translated into a lateral inwards movement of the locking members (20) causing the raised lip portions (23) to disengage with the locking surface (31) and thereby detaching the tablet personal computer (100) from the stand (200); and wherein the hinges (201) and raised lip portions (23) enable the tablet personal computer (100) to be tilted and rotated 360° relative to the stand (200).

### Technical Field

The invention concerns a locking device for releasably attaching a cover of a tablet personal computer to a stand and enabling view plan rotation of the cover relative to the stand.

### BACKGROUND OF THE INVENTION

Tablet personal computers such as the Apple iPad™ and Samsung Galaxy Tab™ are becoming popular consumer electronic devices. A popular use of these tablets is for presentation purposes.

Usually when electronic devices are sold, there are many third party products available for the consumer to complement their purchase. Such products include screen protectors, protective cases, batteries, and ear phones.

To enhance the presentation capability of tablet personal computers, there is a desire for a device that is convenient to transport and operate, and is durable that enables the tablet personal computers to be viewed from multiple viewing angles and different orientations.

### SUMMARY OF THE INVENTION

In a first preferred aspect, there is provided a locking device for releasably attaching a cover of a tablet personal computer to a stand and enabling view plan rotation of the cover relative to the stand, the device comprising:
locking members to releasably engage with a locking surface defined at an edge of a void within the cover;
an actuating member operatively connected to the locking members;
hinges to pivotally connect the locking device to the stand; and
a raised lip portion defined on at peripheral edge of each locking member to engage with the locking surface;
wherein the actuating member is pushed in an inwardly direction by a single finger movement that is translated into a lateral inwards movement of the locking members causing the raised lip portions to disengage with the locking surface and thereby detaching the tablet personal computer from the stand; and
wherein the hinges and raised lip portions enable the tablet personal computer to be tilted and rotated 360° relative to the stand.

The actuating member may be operatively connected to a biasing member at a first end to bias the actuating member in an outwardly direction to maintain the locking device in a locked position, the biasing member being connected at a second end to a positioning pin of a base member that is stationary relative to movement of the actuating member.

The actuating member may be a release button integrally formed with a trigger plate, and the trigger plate has trigger pins received in corresponding guide rails defined in the locking members for translating the inward longitudinal movement of the actuating member to an inward lateral movement of the locking members.

The locking surface may be a circumferential edge of the void and the raised lip portion have a corresponding curved profile.

The biasing member may be a spring.

The base member may have a generally circular shape with a cut-out portion to receive a release button of the actuating member.

The base member may have positioning pins extending upwardly from a bottom surface of the base member that pass through positioning slots defined in the locking members, and through top holes defined in a circular plate, the circular plate for protecting the locking members and trigger plate.

The hinges may be double ended rotational hinges.

Main feature of the present invention include the rotary rail and locking on/off mechanism which are merged into a single unitary body. The rotary rail is also the locking device itself. Triggering a single button using a two finger press operation will move the rail inwards and release the protective shell on the tablet computing device. The protective shell attached to the tablet computing device is able to rotate relative to the stand to both portrait and landscape orientation. The protective shell is also fully detachable from the stand. The angle of view can also be maintained using raised ribs on the stand to abut against the lower edge of the tablet computing device.

### BRIEF DESCRIPTION OF THE DRAWINGS

An example of the invention will now be described with reference to the accompanying drawings, in which:

FIG. 1 is a set of drawings illustrating a locking device changing from a locked position to a fully released position in accordance with an embodiment of the present invention;

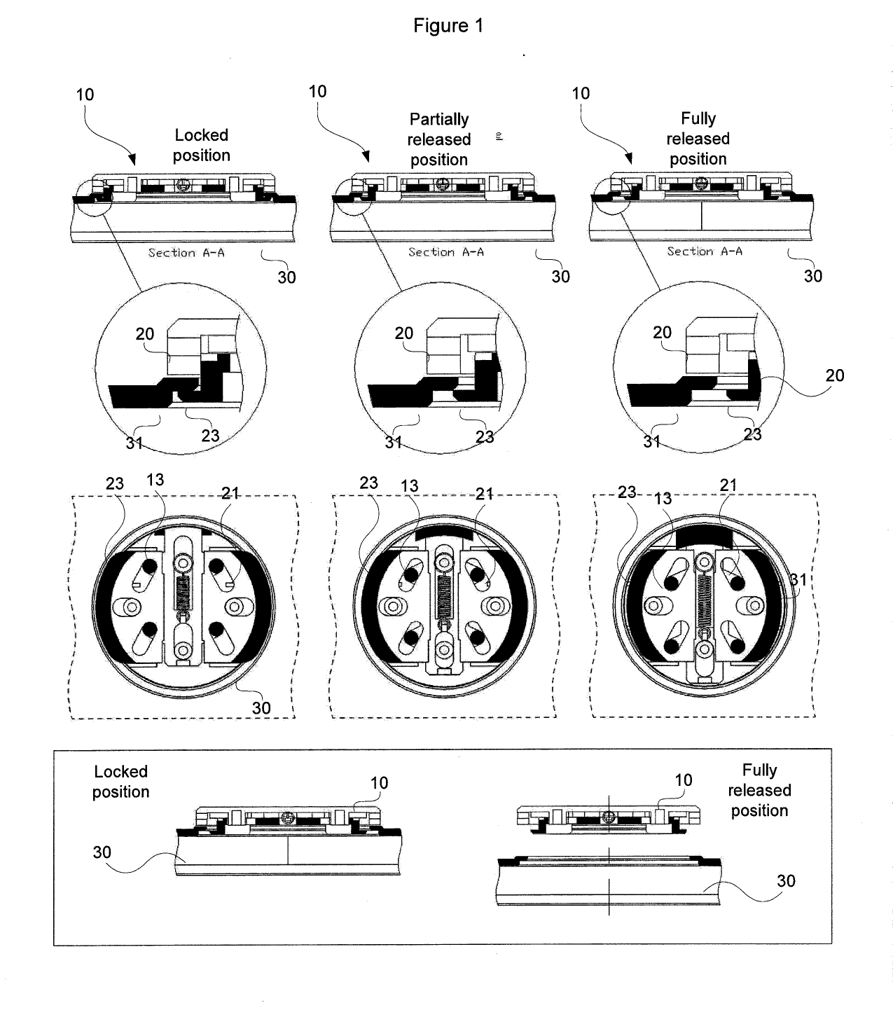

FIG. 2 is a sectional view of the locking device along section A-A in accordance with an embodiment of the present invention;

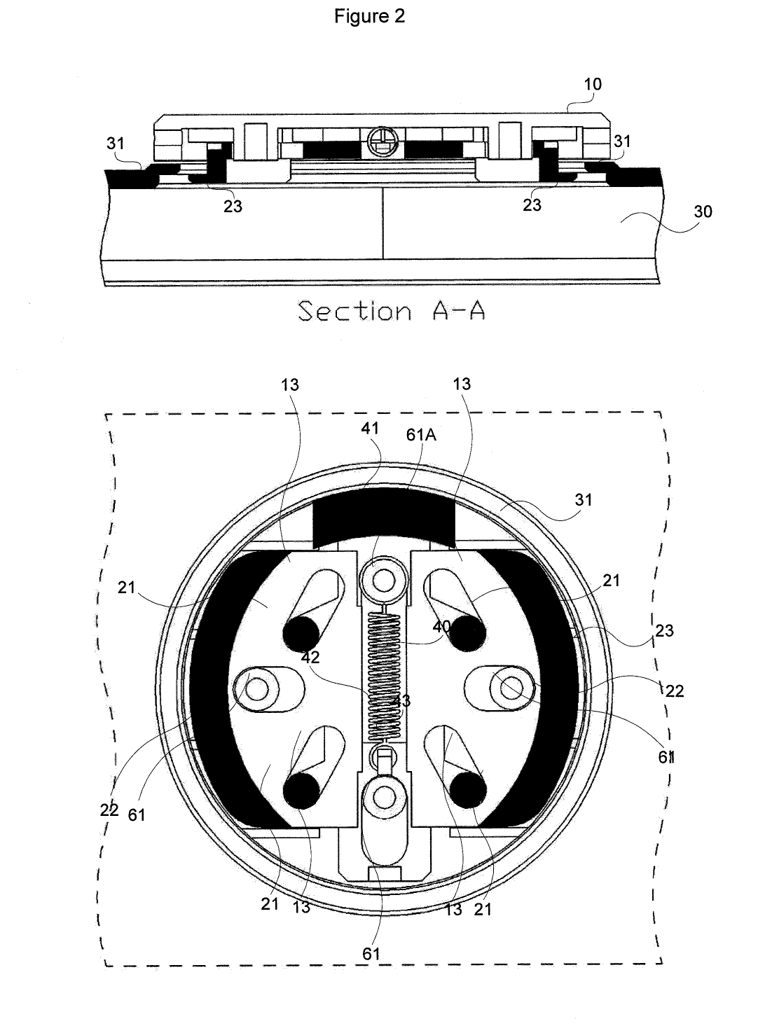

FIG. 3 is a perspective view of the locking device attaching a cover of a tablet personal computer to a stand in a collapsed position in accordance with an embodiment of the present invention;

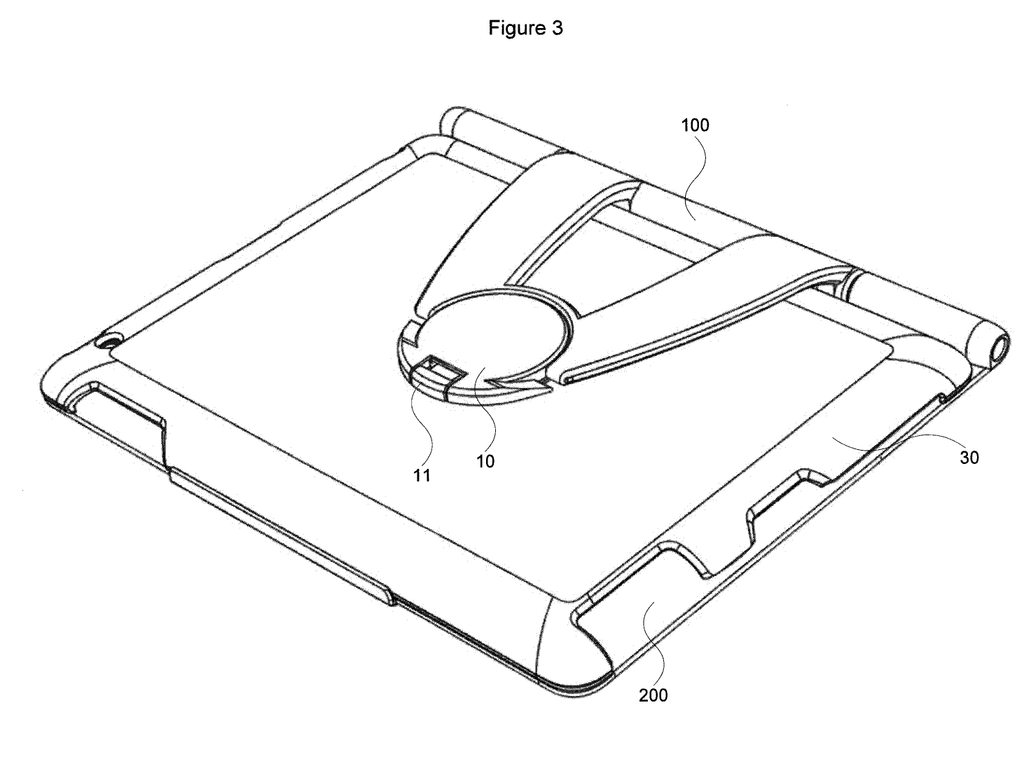

FIG. 4 is a perspective view of the locking device attaching the cover that is not attached to a tablet personal computer to a stand in an expanded position in portrait orientation in accordance with an embodiment of the present invention;

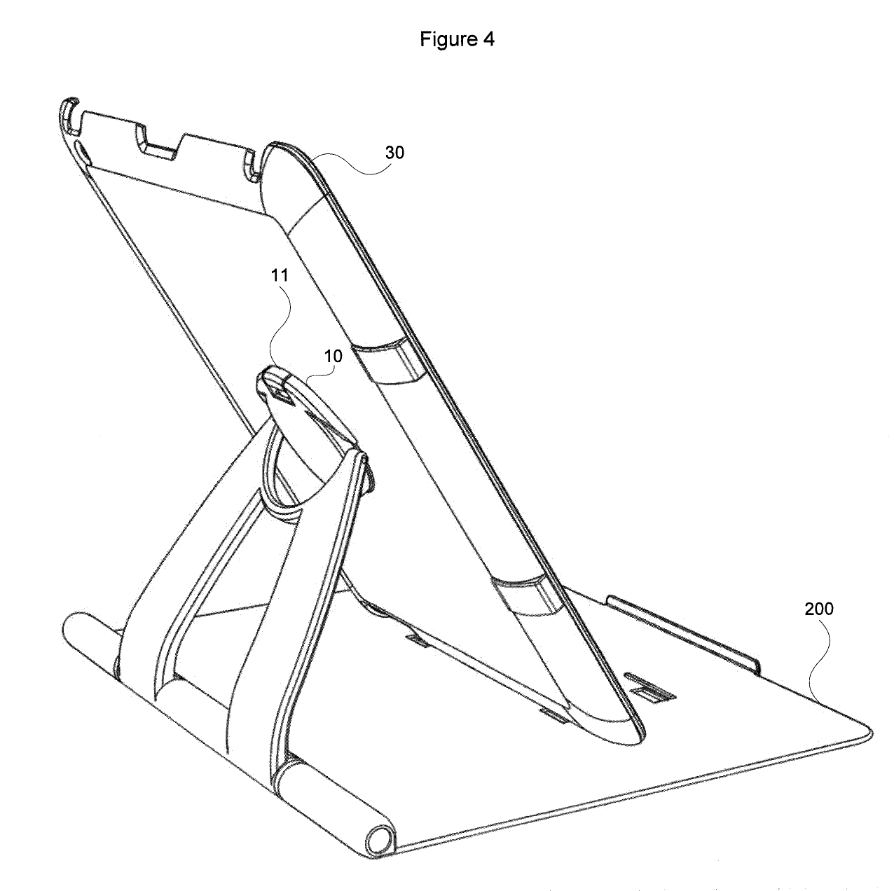

FIG. 5 is a perspective view of the locking device attaching the cover that is not attached to a tablet personal computer to a stand in an expanded position in landscape orientation in accordance with an embodiment of the present invention;

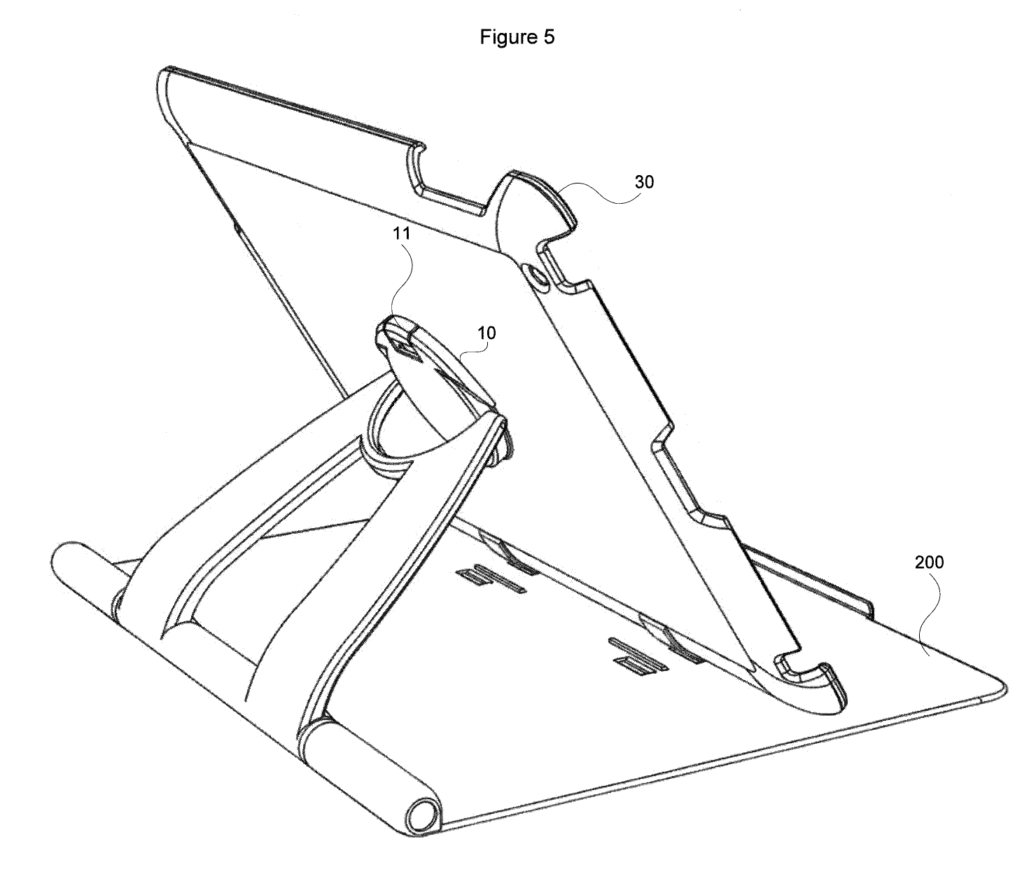

FIG. 6 is a perspective view of the locking device attached to the stand and not to a cover;

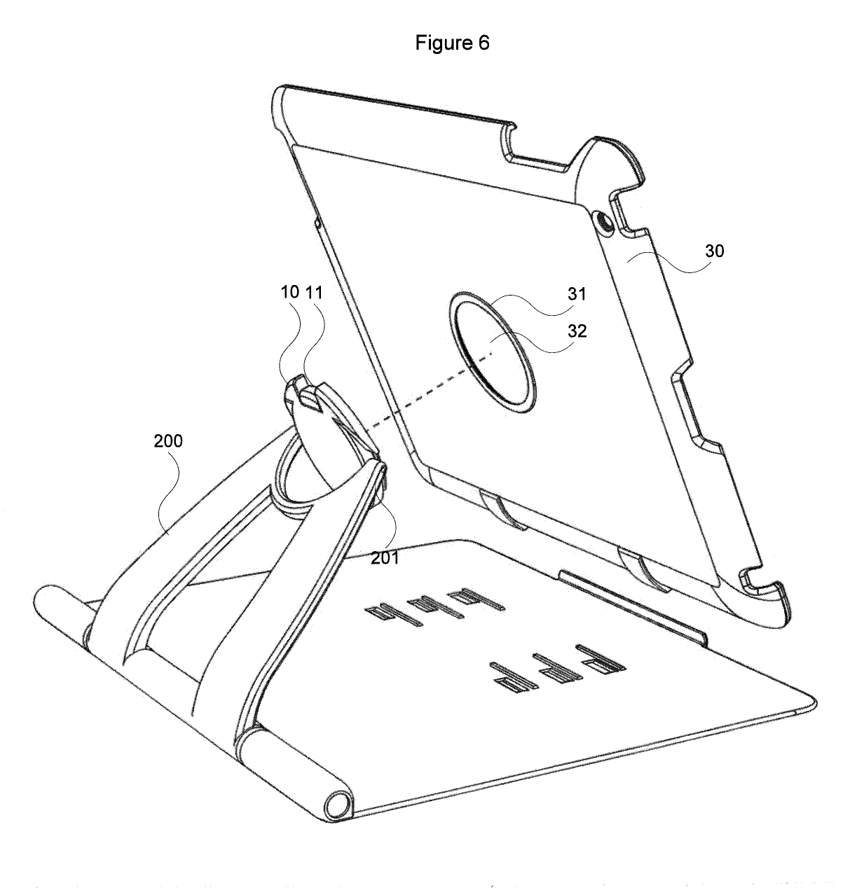

FIG. 7 is an exploded perspective view of the locking device in accordance with an embodiment of the present invention;

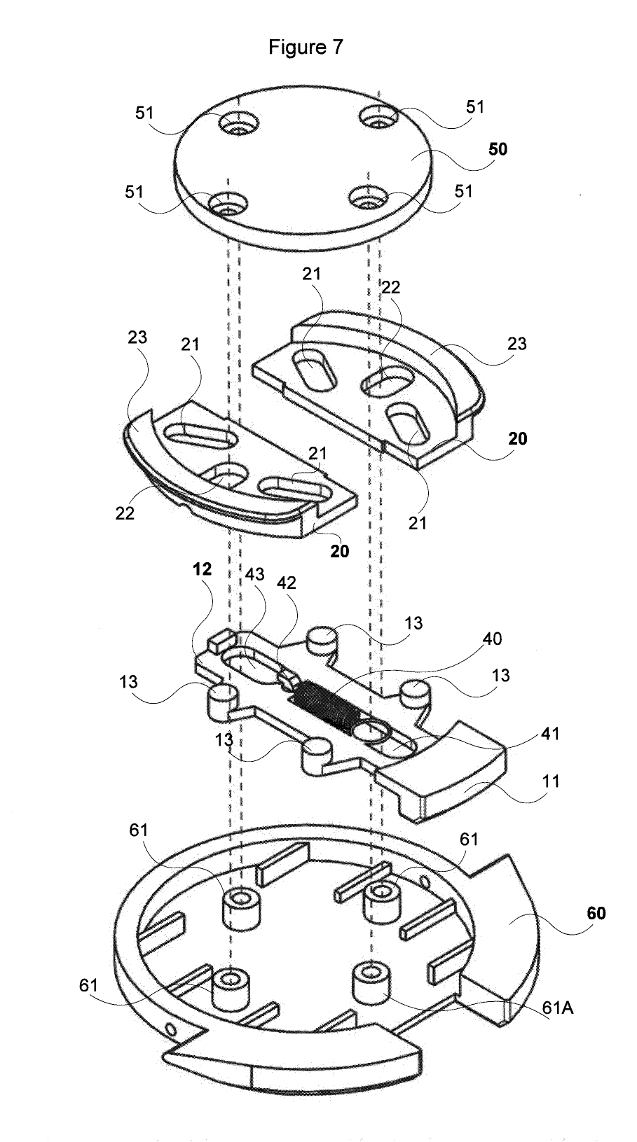

FIG. 8 is a perspective view of the locking device to illustrate the rotational axis about its diameter in accordance with an embodiment of the present invention; and

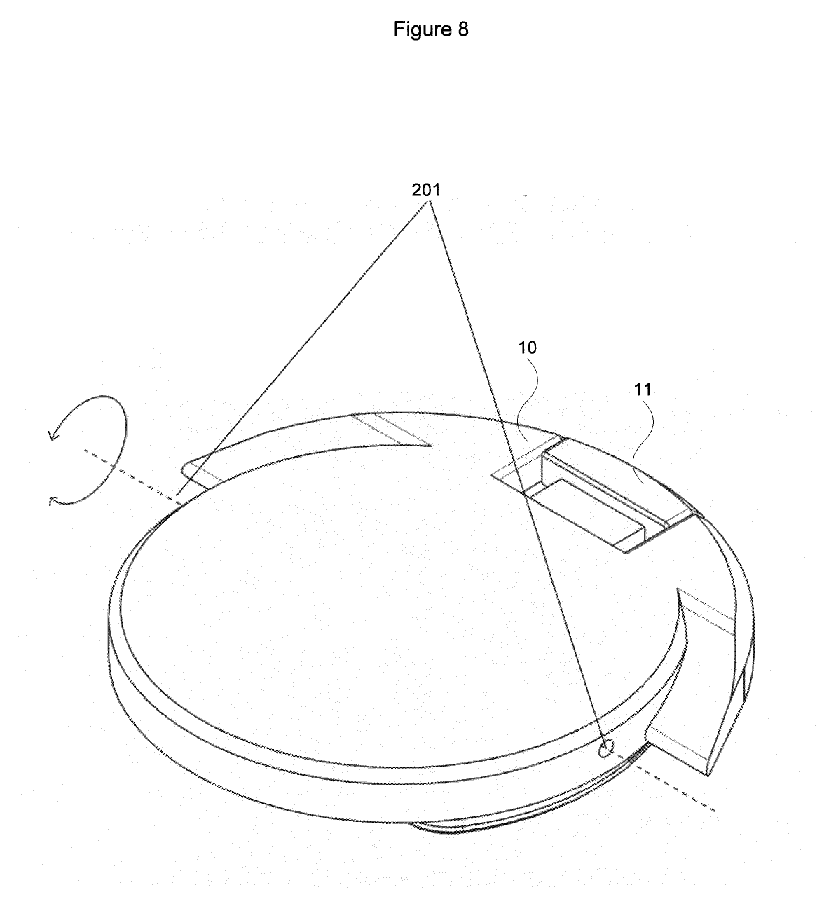

FIG. 9 is a top plan view of the locking device to illustrate the rotational movement of the locking device relative to the cover in accordance with an embodiment of the present invention.

### DETAILED DESCRIPTION OF THE DRAWINGS

Referring to the drawings, a locking device 10 for a releasably attaching a cover 30 of a tablet personal computer 100 to a stand 200 is provided. The cover 30 is fixedly attached to a tablet 100 to protect it from damage, and is usually sold by a third party rather than the manufacturer of the tablet 100. Preferably, the device 10 is pivotally attached to the stand 200 to allow it and the tablet 100 to tilt using double ended rotational hinges. Such an attachment may be provided by pivot pins 201. The device 10 generally comprises a circular plate 50, locking members 20, a trigger plate 12 and a base member 60. The base member 60 is circular which permits the tablet 100 to rotate relative to the stand 200 when attached to the cover 30. The base member 60 has four positioning pins 61 extending upwardly from the bottom surface of base member 60.

The trigger plate 12 is elongate and extends substantially the entire diameter of the base member 60. The trigger plate 12 generally comprises four trigger pins 13 and a trigger rail 41 and a release button 11. The release button 11 is sized and shaped such that it fits snugly in a cut-out portion defined in the peripheral edge of the base member. The trigger rail 41 is an elongate void defined in the trigger plate 12. The trigger pins 13 extend upwardly from the trigger plate 12.

A spring 40 is positioned within the trigger rail 41. A positioning pin 61A also pass through the trigger rail 41, and an opposing positioning pin 61 passes through a second void 43 defined in the trigger plate 12 to prevent lateral movement of the trigger plate 12 relative to the base member 60. The second void 43 defined in the trigger plate 12 is positioned along the same longitudinal axis as the trigger rail 41. A proximal end of the spring 40 is attached to the positioning pin 61A, and the distal end of the spring is attached to a hook 42 provided between the trigger rail and the second void 43. The spring 40 is biased to maintain the locking device 10 in the locked position by keeping the release button 11 in its outermost position. When the release button 11 is pushed inwards, the trigger plate 12 together with the hook 42 also moves inwardly which stretches the spring 40 because the positioning pin 61A that the proximal end of the spring 40 is attached to remains stationary.

The locking members 20 are placed above the trigger plate 12. Each locking member 20 has two guide rails 21 defined within it. The longitudinal axis of the guide rails 21 are at an angle about 30° from the longitudinal axis of the trigger plate 12. The guide tails 21 translate the inward longitudinal movement of the trigger plate 12 into inward lateral movement of both locking members 20. There are two positioning slots 22 defined in the locking members 20 for the two corresponding positioning pins 61 to pass therethrough. The positioning slots 22 are oriented and sized such that they prevent longitudinal movement of the locking members 20 relative to the trigger plate 12 and base member 60. The locking members 20 each have a raised peripheral lip 23 to engage with the cover 30.

The circular plate 50 is fitted over the locking members 20 and trigger plate 12 for protective purposes. The circular plate 50 is held in position by the positioning pins 61 extending from the base member 60 through the top holes 51 in the circulate plate 50.

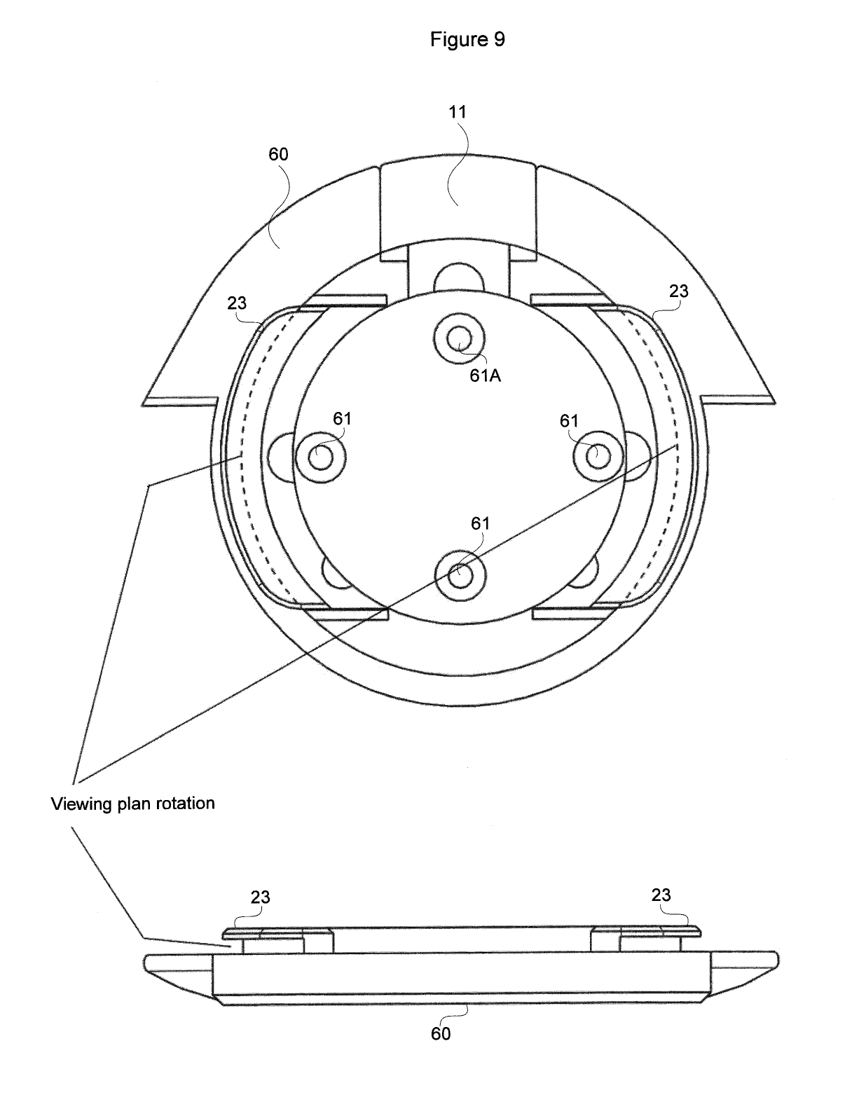

In the locked position, the position of the two locking members 20 are at their greatest distance from each other. The lip 23 of each of the two locking members 20 engage with a locking surface 31 that is defined by a portion of the circumferential surface of a void 32 defined in the cover 30. Therefore, the cover 30 is engaged with the locking device 10 and therefore is engaged with the stand 200 that is operatively attached to the locking device 10. The cross-sectional curvature of the lips 23 co-operate with the void 32 defined in the cover 30 to enable 360° rotation of the locking device 10 relative to the cover 30 when they are engaged together. Turning to FIG. 9, the broken lines indicate the rotational path of the contact between the cover 30 and the locking device 10 when engaged together.

In the partially released position, pushing the release button 11 pushes the trigger plate 12 in an inwardly direction. The trigger pins 13 move within the guide rails 21 and the inwardly pushing force is translated by the guide rails 21 into lateral inward movement of the locking members 20. The spring 40 is also extended when the released button 11 is pushed therefore storing potential energy generated by the pushing force. The cover 30 still remains unable to be fully detached because some portion the lip 23 of the locking member 20 is still engaged with the locking surface 31.

In the fully released position, the trigger plate 12 is moved into the final open position. The trigger pins 13 of the trigger plate 12 have moved to their innermost position determined by the guide rails 21 of the locking members 20. The locking members 20 have moved to their closest position. The lip 23 of the locking member 20 is now disengaged from the locking surface 31. Therefore, the cover 30 can be fully detached from the locking device 10.

The locking device 10 has a small size, is light-weight, reliable, and durable as there are few moving parts. The attachment is secure because the locking surface 31 is spread over a significant surface area rather than a single point of attachment and therefore the load is spread over a larger surface area. The locking device 10 enables 360° rotation of the tablet 100 relative to the stand 200, and tilting of the table 100 relative to the stand 200 by an appropriate pivotal attachment. Therefore convenient multiple viewing angles is provided. Rotation of the tablet 100 enables it to be viewed in portrait or landscape orientation.

The locking device 10 has a single button releasing system provided by the release button 11. A single finger pushing action permits quick release and engagement of the tablet 100 to with the stand 200.

Although a spring has been described, it is envisaged any type of biasing member, for example, a member made from an elastic material, is possible.

Although four trigger pins 13 and four guide rails 21 have been described, it is envisaged that other shapes and quantity of trigger pins 13 and guide rails 21 may be possible.

It will be appreciated by persons skilled in the art that numerous variations and/or modifications may be made to the invention as shown in the specific embodiments without departing from the scope or spirit of the invention as broadly described. The present embodiments are, therefore, to be considered in all respects illustrative and not restrictive.

We claim:

1. A locking device for releasably attaching a cover of a tablet personal computer to a stand and enabling view plan rotation of the cover relative to the stand, the device comprising:
locking members to releasably engage with a locking surface defined at an edge of a void within the cover;
an actuating member operatively connected to the locking members;
hinges to pivotally connect the locking device to the stand; and
a raised lip portion defined on at peripheral edge of each locking member to engage with the locking surface;
wherein the actuating member is pushed in an inwardly direction by a single finger movement that is translated into a lateral inwards movement of the locking members causing the raised lip portions to disengage with the locking surface and thereby detaching the tablet personal computer from the stand; and
wherein the hinges and raised lip portions enable the tablet personal computer to be tilted and rotated 360° relative to the stand.

2. The device according to claim 1, wherein the actuating member is operatively connected to a biasing member at a first end to bias the actuating member in an outwardly direction to maintain the locking device in a locked position, the biasing member being connected at a second end to a positioning pin of a base member that is stationary relative to movement of the actuating member.

3. The device according to claim 1, wherein the actuating member is a release button integrally formed with a trigger plate, and the trigger plate has trigger pins received in corresponding guide rails defined in the locking members for translating the inward longitudinal movement of the actuating member to an inward lateral movement of the locking members.

4. The device according to claim 1, wherein the locking surface is a circumferential edge of the void and the raised lip portion have a corresponding curved profile.

5. The device according to claim 3, wherein the biasing member is a spring.

6. The device according to claim 2, wherein the base member has a generally circular shape with a cut-out portion to receive a release button of the actuating member.

7. The device according to claim 6, wherein the base member has positioning pins extending upwardly from a bottom surface of the base member that pass through positioning slots defined in the locking members, and through top holes defined in a circular plate, the circular plate for protecting the locking members and trigger plate.

8. The device according to claim 1, wherein the hinges are double ended rotational hinges.
